(19) United States
(12) Patent Application Publication
(10) Pub. No.: US 2025/0201548 A1
(43) Pub. Date: Jun. 19, 2025

(54) METHODS OF DEPOSITING SILICON-CONTAINING DIELECTRIC LAYERS FOR SEMICONDUCTOR DEVICES

(71) Applicants: Applied Materials, Inc., Santa Clara, CA (US); National University of Singapore, Singapore (SG)

(72) Inventors: Zhijie Chua, Singapore (SG); Sao Chuan Yeh, Singapore (SG); Andrea Leoncini, Singapore (SG); Xinke Wang, Singapore (SG); Jiecong Tang, Singapore (SG); John Sudijono, Singapore (SG); Anil Kumar Tummanapelli, Singapore (SG); Richard Ming Wah Wong, Singapore (SG); Syed Nizar Syed Abdulrahim, Singapore (SG)

(73) Assignees: Applied Materials, Inc., Santa Clara, CA (US); National University of Singapore, Singapore (SG)

(21) Appl. No.: 18/541,263

(22) Filed: Dec. 15, 2023

(51) Int. Cl. H01L 21/02; C23C 16/02; C23C 16/30; C23C 16/34; C23C 16/40; C23C 16/455

(52) U.S. Cl. CPC H01L 21/02211; C23C 16/0227; C23C 16/308; C23C 16/345; C23C 16/401; C23C 16/45527; C23C 16/45553; H01L 21/0214; H01L 21/02164; H01L 21/0217; H01L 21/0228; H01L 21/02301

(57) ABSTRACT

Methods of depositing silicon-containing layers in the formation of semiconductor devices are described. The methods include a thermal chemical vapor deposition (CVD) process or a thermal atomic layer deposition (ALD) process without the use of plasma. Some methods include exposing a semiconductor substrate to a silicon-containing precursor, an oxygen-containing reactant, and an initiator compound to deposit a silicon oxide layer. Some methods include exposing a semiconductor substrate to a silicon-containing precursor, a nitrogen-containing reactant, and an initiator compound to deposit a silicon nitride layer. Some methods include exposing a semiconductor substrate to a silicon-containing precursor, an oxygen-containing reactant, a nitrogen-containing reactant, and an initiator compound to deposit a silicon oxynitride layer.

### TECHNICAL FIELD

Embodiments of the present disclosure pertain to the field of semiconductor device manufacturing. More particularly, embodiments of the disclosure are directed to methods of depositing silicon-containing layers, such as silicon oxide layers, silicon nitride layers, and/or silicon oxynitride layers, in the formation of semiconductor devices.

### BACKGROUND

Dielectric deposition involves creating a layer of material with insulating properties on a substrate or surface. The dielectric layer acts as an electrical insulator and is used in numerous types of electronic devices and semiconductor devices. Silicon oxide and silicon nitride have been and continue to be commonly used suitable dielectric materials for many semiconductor applications.

Current silicon oxide deposition processes use oxidation pathways that employ “strong” oxidants, such as oxygen (O₂) plasma or ozone (O₃), which results in damage to the surrounding semiconductor structures due to strong oxidizing properties of the oxygen (O₂) plasma and ozone (O₃). In current silicon oxide deposition processes, the silicon oxide deposition rate with “milder” oxidants such as sulfoxides, amine N-oxides, or phosphine oxides, is slow or fails to deposit silicon oxide at all. Other oxidants such as nitrous oxide (N₂O), for example, require plasma activation.

Current silicon oxide deposition processes may also include hydrogen peroxide (H₂O₂) oxidation pathways, which have limitations of higher temperatures and poor long term stability of the oxidant. Other thermal processes using oxygen (O₂) require high temperatures, such as greater than 600° C.

Initiated chemical vapor deposition (iCVD) processes employ an initiator compound (e.g., peroxide) to initiate the polymerization of unsaturated alkyl monomer to deposit silicon-carbon polymer films. More particularly, current iCVD processes focus on a single monomer/precursor that undergoes commonly known radical polymerization process due to the presence of a radical initiator and suitable functional groups on a monomer (e.g., vinyl) for film deposition. Milder oxidants, such as sulfoxides, amine N-oxides, or phosphine oxide either do not react with silicon-containing precursors to deposit a silicon oxide layer, or have slow deposition rates.

Current silicon nitride deposition processes also typically use plasma, which results in damage to the surrounding semiconductor structures. Current thermal silicon nitride deposition processes use halosilanes and nitrogen co-reagents, but deposit poor quality layers having high hydrogen content.

Accordingly, there is a need in the art for improved methods of depositing high-quality silicon-containing dielectric layers without damaging the surrounding semiconductor structures.

### SUMMARY

One or more embodiments of the disclosure are directed to a method of manufacturing a semiconductor device. The method comprises exposing a semiconductor substrate in a semiconductor processing chamber to a silicon-containing precursor, an oxygen-containing reactant, and an initiator compound to deposit a silicon oxide layer. The initiator compound reacts with one or more of the silicon-containing precursor or the oxygen-containing reactant to form an activated silicon-containing precursor and/or an activated oxygen-containing reactant.

Additional embodiments of the disclosure are directed to a method of manufacturing a semiconductor device. The method comprises exposing a semiconductor substrate in a semiconductor processing chamber to a silicon-containing precursor, a nitrogen-containing reactant, and an initiator compound to deposit a silicon nitride layer. The initiator compound reacts with one or more of the silicon-containing precursor or the nitrogen-containing reactant to form an activated silicon-containing precursor and/or an activated nitrogen-containing reactant.

Further embodiments of the disclosure are directed to a method of manufacturing a semiconductor device. The method comprises exposing a semiconductor substrate in a semiconductor processing chamber to a silicon-containing precursor, an oxygen-containing reactant, a nitrogen-containing reactant, and an initiator compound to deposit a silicon oxynitride layer. The initiator compound reacts with one or more of the silicon-containing precursor, the oxygen-containing reactant, or the nitrogen-containing reactant to form an activated silicon-containing precursor, an activated oxygen-containing reactant, and/or an activated nitrogen-containing reactant.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the Figures of the accompanying drawings in which like references indicate similar elements.

FIG. 1A illustrates a process flow diagram of a method of manufacturing a semiconductor device according to one or more embodiments of the present disclosure;

FIG. 1B illustrates a cross-sectional view of a semiconductor device according to one or more embodiments of the present disclosure;

FIG. 1C illustrates a cross-sectional view of a semiconductor device according to one or more embodiments of the present disclosure;

FIG. 1D illustrates a cross-sectional view of a semiconductor device according to one or more embodiments of the present disclosure;

FIG. 2A illustrates a process flow diagram of a method of manufacturing a semiconductor device according to one or more embodiments of the present disclosure;

FIG. 2B illustrates a cross-sectional view of a semiconductor device according to one or more embodiments of the present disclosure;

FIG. 2C illustrates a cross-sectional view of a semiconductor device according to one or more embodiments of the present disclosure;

FIG. 2D illustrates a cross-sectional view of a semiconductor device according to one or more embodiments of the present disclosure;

FIG. 3A illustrates a process flow diagram of a method of manufacturing a semiconductor device according to one or more embodiments of the present disclosure;

FIG. 3B illustrates a cross-sectional view of a semiconductor device according to one or more embodiments of the present disclosure;

FIG. 3C illustrates a cross-sectional view of a semiconductor device according to one or more embodiments of the present disclosure;

FIG. 3D illustrates a cross-sectional view of a semiconductor device according to one or more embodiments of the present disclosure; and

FIG. 4 illustrates a cluster tool according to one or more embodiments of the present disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “about” as used herein means approximately or nearly and in the context of a numerical value or range set forth means a variation of ±15%, or less, of the numerical value. For example, a value differing by ±14%, ±10%, ±5%, ±2%, or ±1%, would satisfy the definition of about.

Spatially relative terms, such as “beneath,” “below,” “lower,” “above,” “upper” and the like, may be used herein for ease of description to describe one element's relationship to another element(s) or feature(s) as illustrated in the Figures. It will be understood that the spatially relative terms are intended to encompass different orientations of the semiconductor device in use or operation in addition to the orientation depicted in the Figures. For example, if the semiconductor device in the Figures is turned over, elements described as “below” or “beneath” other elements would then be oriented “above” the other elements. Thus, the exemplary term “below” may encompass both an orientation of above and below. The semiconductor device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments,” “some embodiments,” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in some embodiments,” “in one embodiment,” or “in an embodiment” in various places throughout this specification are not necessarily referring to the same embodiment of the disclosure. In one or more embodiments, the particular features, structures, materials, or characteristics are combined in any suitable manner.

As used herein, the term “substrate” or “wafer” refers to a surface, or portion of a surface, upon which a process acts. It will also be understood by those skilled in the art that reference to a substrate can refer to only a portion of the substrate, unless the context clearly indicates otherwise. Additionally, reference to depositing on a substrate can mean both a bare substrate and a substrate with one or more layers or features deposited or formed thereon.

A “substrate” as used herein, refers to any substrate or material surface formed on a substrate upon which layer processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, and any other materials such as metals, metal nitrides, metal alloys, and other conductive materials, depending on the application. Substrates include, without limitation, semiconductor wafers. In some embodiments, the semiconductor substrate comprises one or more of doped or undoped crystalline silicon (Si), doped or undoped crystalline silicon germanium (SiGe), doped or undoped amorphous silicon (Si), or doped or undoped amorphous silicon germanium (SiGe). Substrates may be exposed to a pretreatment process to polish, etch, reduce, oxidize, hydroxylate, anneal and/or bake the substrate surface. In addition to layer processing directly on the surface of the substrate itself, in the present disclosure, any of the layer processing steps disclosed may also be performed on an under-layer formed on the substrate as disclosed in more detail below, and the term “substrate surface” is intended to include such under-layer as the context indicates. Thus, for example, where a layer/layer or partial layer/layer has been deposited onto a substrate surface, the exposed surface of the newly deposited layer/layer becomes the substrate surface.

For the avoidance of doubt, no stoichiometric ratios are implied by the identification of materials disclosed herein. For example, a silicon oxide (SiO) material contains silicon and oxygen, a silicon nitride (SiN) material contains silicon and nitrogen, and a silicon oxynitride (SiON) material contains silicon, oxygen, and nitrogen. These elements may or may not be present at a 1:1 ratio, or a 1:1:1 ratio, unless otherwise specified herein.

It will be appreciated that the methods described herein can be implemented on any substrate surface having one or more features formed therein, one or more layers formed thereon, and combinations thereof. The shape of the feature can be any suitable shape including, but not limited to, trenches, holes and vias (circular or polygonal). As used in this regard, the term “feature” refers to any intentional surface irregularity. Suitable examples of features include but are not limited to trenches, which have a top, two sidewalls and a bottom extending into the substrate, vias which have one or more sidewall extending into the substrate to a bottom, and slot vias. The features described herein can have any suitable aspect ratio (ratio of the depth of the feature to the width of the feature). In one or more embodiments, the aspect ratio of the features described herein is greater than or equal to about 1:1, 2:1, 5:1, 10:1, 15:1, 20:1, 25:1, 30:1, 35:1, or 40:1.

The term “on” indicates that there is direct contact between elements. The term “directly on” indicates that there is direct contact between elements with no intervening elements.

As used herein, the term “in situ” refers to processes that are all performed in the same processing chamber or within different processing chambers that are connected as part of an integrated processing system, such that each of the processes are performed without an intervening vacuum break. As used herein, the term “ex situ” refers to processes that are performed in at least two different processing chambers such that one or more of the processes are performed with an intervening vacuum break. In some embodiments, processes are performed without breaking vacuum or without exposure to ambient air.

As used herein, the terms “precursor,” “reactant,” “reactive gas,” “reactive species,” and the like are used interchangeably to refer to any gaseous species that can react with the substrate surface.

As used herein, the term “chemical vapor deposition” refers to the exposure of at least one reactive species to deposit a layer of material on the substrate surface. In some embodiments, the chemical vapor deposition (CVD) process comprises mixing the two or more reactive species in the processing chamber to allow gas phase reactions of the reactive species and deposition. In some embodiments, the CVD process comprises exposing the substrate surface to two or more reactive species simultaneously. In some embodiments, the CVD process comprises exposing the substrate surface to a first reactive species continuously with an intermittent exposure to a second reactive species. In some embodiments, the substrate surface undergoes the CVD reaction to deposit a layer having a predetermined thickness. In the CVD process, the layer can be deposited in one exposure to the mixed reactive species or can be multiple exposures to the mixed reactive species with purges between. In some embodiments, the substrate surface is exposed to the first reactive species and the second reactive species substantially simultaneously.

As used herein, “substantially simultaneously” means that most of the duration of the first reactive species exposure overlaps with the second reactive species exposure.

As used herein, the term “purging” includes any suitable purge process that removes unreacted precursor, reaction products and by-products from the process region. The suitable purge process includes moving the substrate through a gas curtain to a portion or sector of the processing region that contains none or substantially none of the reactant. In one or more embodiments, purging the processing chamber comprises applying a vacuum. In some embodiments, purging the processing region comprises flowing a purge gas over the substrate. In some embodiments, the purge process comprises flowing an inert gas. In one or more embodiments, the purge gas is selected from one or more of nitrogen (N₂), helium (He), and argon (Ar). In some embodiments, the first reactive species is purged from the reaction chamber for a time duration in a range of from 0.1 seconds to 30 seconds, from 0.1 seconds to 10 seconds, from 0.1 seconds to 5 seconds, from 0.5 seconds to 30 seconds, from 0.5 seconds to 10 seconds, from 0.5 seconds to 5 seconds, from 1 seconds to 30 seconds, from 1 seconds to 10 seconds, from 1 seconds to 5 seconds, from 5 seconds to 30 seconds, from 5 seconds to 10 seconds or from 10 seconds to 30 seconds before exposing the substrate to the second reactive species.

“Cyclical deposition” or “atomic layer deposition” (ALD) refers to the sequential exposure of two or more reactive species to deposit a layer of material on a substrate surface. The substrate, or portion of the substrate, is exposed separately to the two or more reactive species which are introduced into a reaction zone of a processing chamber. In a time-domain ALD process, exposure to each reactive species is separated by a time delay to allow each compound to adhere and/or react on the substrate surface and then be purged from the processing chamber. These reactive species are said to be exposed to the substrate sequentially. In a spatial ALD process, different portions of the substrate surface, or material on the substrate surface, are exposed simultaneously to the two or more reactive species so that any given point on the substrate is substantially not exposed to more than one reactive species simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay, a purge gas, such as argon, is introduced into the processing chamber to purge the reaction zone or otherwise remove any residual reactive species or reaction by-products from the reaction zone. Alternatively, the purge gas may flow continuously throughout the deposition process so that only the purge gas flows during the time delay between pulses of reactive species. The reactive species are alternatively pulsed until a desired layer or layer thickness is formed on the substrate surface. In either scenario, the ALD process of pulsing compound A, purge gas, compound B and purge gas is a cycle. A cycle can start with either compound A or compound B and continue the respective order of the cycle until achieving a layer with the predetermined thickness.

One or more of the layers deposited on the substrate or substrate surface are continuous. As used herein, the term “continuous” refers to a layer that covers an entire exposed surface without gaps or bare spots that reveal material underlying the deposited layer. A continuous layer may have gaps or bare spots with a surface area less than about 15% or less than about 10% of the total surface area of the layer.

Embodiments of the present disclosure advantageously provide methods of depositing high-quality silicon-containing layers, such as silicon oxide, silicon nitride, and/or silicon oxynitride layers, without damaging the surrounding semiconductor structures. Some embodiments advantageously provide methods of depositing silicon-containing layers directly on a semiconductor substrate surface.

Some embodiments advantageously provide thermal methods of depositing silicon-containing layers without the use of plasma. Thermal methods that eliminate plasma from the process simplify the hardware requirements, making the manufacturing system less complex. In addition, one or more embodiments of the thermal processes of the disclosure provide improved productivity and performance in terms of fewer particles and a reduced number of mean wafers between cleans (MWBC).

The embodiments of the disclosure are described by way of the Figures, which illustrate semiconductor devices and methods of manufacturing semiconductor devices in accordance with one or more embodiments of the disclosure. The processes shown are merely illustrative possible uses for the disclosed processes, and the skilled artisan will recognize that the disclosed processes are not limited to the illustrated applications.

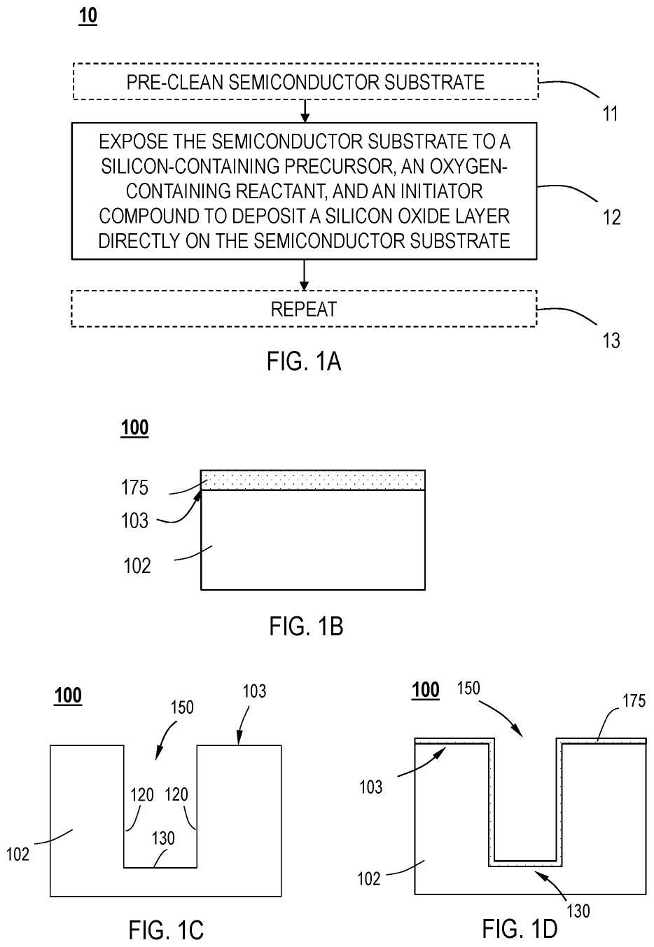

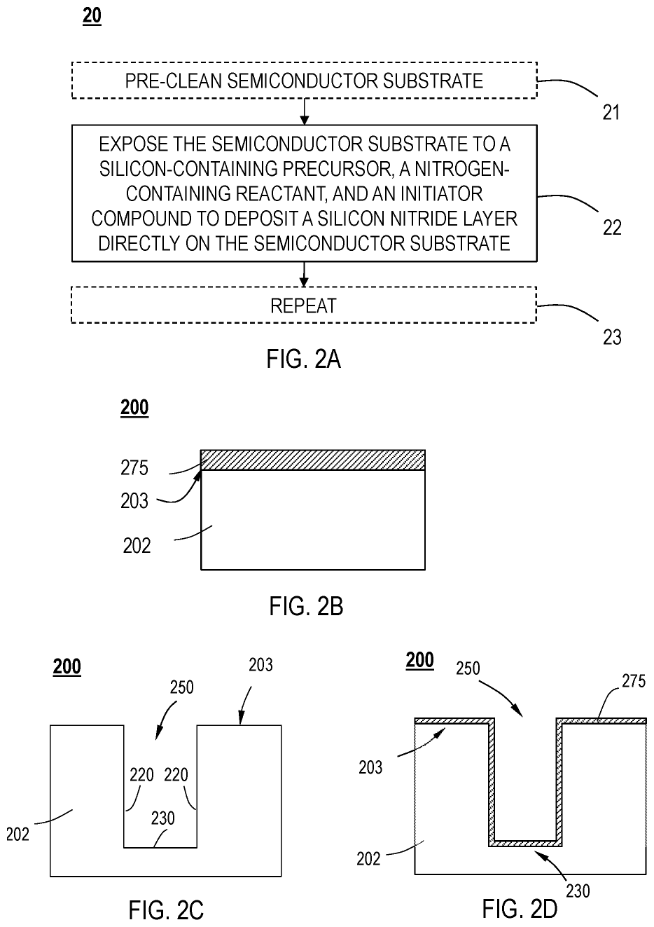

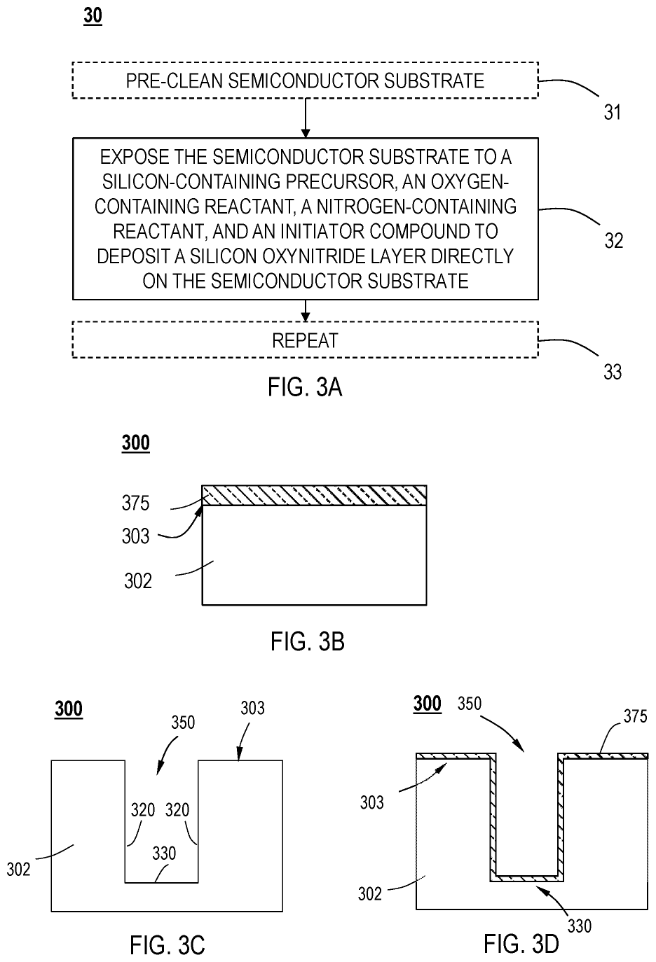

FIG. 1A illustrates a process flow diagram of a method 10 of manufacturing a semiconductor device 100 according to one or more embodiments of the present disclosure. FIGS. 1B-1D illustrate embodiments of the semiconductor device 100 manufactured in accordance with the method 10. FIG. 2A illustrates a process flow diagram of a method 20 of manufacturing a semiconductor device 200 according to one or more embodiments of the present disclosure. FIGS. 2B-2D illustrate embodiments of the semiconductor device 200 manufactured in accordance with the method 20. FIG. 3A illustrates a process flow diagram of a method 30 of manufacturing a semiconductor device 300 according to one or more embodiments of the present disclosure. FIGS. 3B-3D illustrate embodiments of the semiconductor device 300 manufactured in accordance with the method 30.

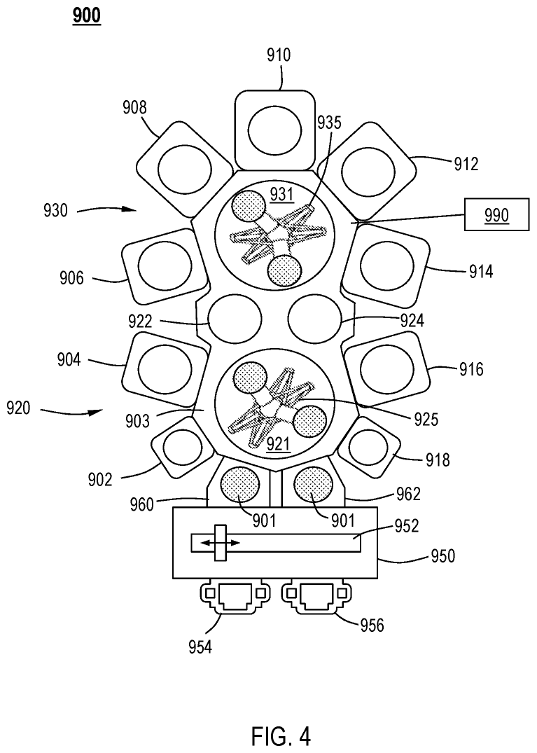

FIG. 4 illustrates a cluster tool 900 in which any of the semiconductor devices described herein, e.g., semiconductor device 100, semiconductor device 200, or semiconductor device 300 can be manufactured and any of the methods described herein e.g., method 10, method 20, or method 30 can be performed.

Referring to FIGS. 1A-1D, in one or more embodiments, the method 10 comprises pre-cleaning a semiconductor substrate 102 in a semiconductor processing chamber to remove native oxides (operation 11); exposing the semiconductor substrate 102 to a silicon-containing precursor, an oxygen-containing reactant, and an initiator compound to deposit a silicon oxide layer 175 directly on a top surface 103 of the semiconductor substrate 102 (operation 12); and optionally, repeating one or more operations of the method 10 (operation 13).

In some embodiments, the method 10 comprises operation 11, operation 12, and operation 13. In some embodiments, the method 10 comprises operation 11 and operation 12. In some embodiments, the method 10 comprises operation 12. In some embodiments, the method 10 consists essentially of operation 11, operation 12, and operation 13. In some embodiments, the method 10 consists essentially of operation 11 and operation 12. In some embodiments, the method 10 consists essentially of operation 12. In some embodiments, the method 10 consists of operation 11, operation 12, and operation 13. In some embodiments, the method 10 consists of operation 11 and operation 12. In some embodiments, the method 10 consists of operation 12.

The semiconductor substrate 102 can include any suitable substrate material. In one or more embodiments, the semiconductor substrate 102 comprises a semiconductor material, e.g., silicon (Si), carbon (C), germanium (Ge), silicon germanium (SiGe), gallium arsenide (GaAs), indium phosphate (InP), indium gallium arsenide (InGaAs), indium aluminum arsenide (InAlAs), germanium (Ge), silicon germanium (SiGe), other semiconductor materials, or any combination thereof. In one or more embodiments, the semiconductor substrate 102 comprises one or more of silicon (Si), germanium (Ge), gallium (Ga), arsenic (As), indium (In), phosphorus (P), or selenium (Se). In some embodiments, the semiconductor substrate 102 comprises one or more of doped or undoped crystalline silicon (Si), doped or undoped crystalline silicon germanium (SiGe), doped or undoped amorphous silicon (Si), or doped or undoped amorphous silicon germanium (SiGe).

The method 10 includes pre-cleaning the semiconductor substrate 102 at operation 11. In one or more embodiments, keeping the pre-cleaning process under vacuum ensures that no oxide is introduced/formed on the semiconductor substrate 102 during the method. At operation 11, pre-cleaning the semiconductor substrate 102 removes native oxides from the surface of the semiconductor substrate 102. The pre-cleaning process of operation 11 can be any suitable process. In some embodiments, the pre-cleaning process is a wet etch process or a dry etch process. In some embodiments, the pre-cleaning process includes using a SC-1 solution comprising one or more of ozone, ammonium hydroxide or hydrogen peroxide. In some embodiments, the pre-cleaning process includes using a SC-1 solution without ozone, ammonium hydroxide or hydrogen peroxide. In some embodiments, after using the SC-1 solution, the pre-cleaning process includes using dilute hydrofluoric acid (dilute HF), including greater than 100:1, such as 130:1 dilute HF, to etch away native oxide on the semiconductor substrate 102. In some embodiments, the pre-cleaning process includes using one or more gases of ammonia (NH₃), hydrofluoric acid (HF), nitrogen trifluoride (NF₃), or water (H₂O) with or without plasma at a temperature in a range of from −50° C. to 150° C.

In some embodiments, at operation 12, the method 10 includes exposing the semiconductor substrate 102 to a silicon-containing precursor, an oxygen-containing reactant, and an initiator compound to deposit a silicon oxide layer 175 on or directly on a top surface 103 of the semiconductor substrate 102. Each of the silicon-containing precursor, the oxygen-containing reactant, and the initiator compound may be suitable for vapor delivery. In some embodiments, operation 12 includes a thermal chemical vapor deposition (CVD) process or a thermal atomic layer deposition (ALD) process.

The silicon-containing precursor, the oxygen-containing reactant, and the initiator compound can be flowed in any suitable order to deposit the silicon oxide layer 175. In some embodiments, the silicon-containing precursor, the oxygen-containing reactant, and the initiator compound are flowed individually in a sequential order. In some embodiments, one or more of the silicon-containing precursor, the oxygen-containing reactant, and the initiator compound are flowed simultaneously together (e.g., co-flowed).

In some embodiments, the silicon-containing precursor, the oxygen-containing reactant, and the initiator compound are flowed sequentially in the order of the silicon-containing precursor, then the oxygen-containing reactant, then the initiator compound. In some embodiments, the silicon-containing precursor, the oxygen-containing reactant, and the initiator compound are flowed sequentially in the order of the oxygen-containing reactant, then the silicon-containing precursor, then the initiator compound. In some embodiments, the silicon-containing precursor, the oxygen-containing reactant, and the initiator compound are flowed sequentially in the order of the initiator compound, then the silicon-containing precursor, then the oxygen-containing reactant.

In some embodiments, the silicon-containing precursor, the oxygen-containing reactant, and the initiator compound are flowed simultaneously together (e.g., co-flowed).

In some embodiments, the silicon-containing precursor is flowed, followed by co-flowing the oxygen-containing reactant and the initiator compound. The oxygen-containing reactant and the initiator compound can be flowed for the same duration of time or different durations of time.

In one or more embodiments, the silicon-containing precursor and the initiator compound are co-flowed, followed by flowing the oxygen-containing reactant. The silicon-containing precursor and the initiator compound can be flowed for the same duration of time or different durations of time.

In specific embodiments, operation 12 of method 10 is a pulsed CVD (pCVD) method where one or more of the silicon-containing precursor, the oxygen-containing reactant, and the initiator compound are flowed constantly, and at least one of the other of the silicon-containing precursor, the oxygen-containing reactant, and the initiator compound is pulsed at a regular interval (e.g., pulsed intermittently) into the semiconductor processing chamber. In specific embodiments where operation 12 of method 10 is a pulsed CVD (pCVD) method, the silicon-containing precursor and the oxygen-containing reactant are flowed constantly and the initiator compound is pulsed intermittently.

The silicon-containing precursor may be any suitable precursor. In some embodiments, the silicon-containing precursor comprises one or more of a silane, an aminosilane, a silylamine, a thiosilane, a halosilane, or an alkoxysilane. In one or more embodiments, the silicon-containing precursor comprises tetrakis(ethylsulfanyl) silane. In one or more embodiments, the silicon-containing precursor comprises tetrakis(2,2,2-trifluoroethyl)tetrathiosilicate. In one or more embodiments, the silicon-containing precursor comprises tetrakis(phenylsulfanyl) silane. In one or more embodiments, the silicon-containing precursor comprises tetrakis(dimethylamino) silane (4DMAS). In one or more embodiments, the silicon-containing precursor comprises tris(dimethylamino) silane (3DMAS). In one or more embodiments, the silicon-containing precursor comprises bis(diethylamino)silane (BDEAS). The silicon-containing precursor may be flowed at any suitable flow rate and the flow rate may be adjusted based on the particular application.

The oxygen-containing reactant may be any suitable reactant. In some embodiments, the oxygen-containing reactant comprises one or more of a sulfoxide, an amine N-oxide, or a phosphine oxide. In some embodiments, the oxygen-containing reactant comprises dimethyl sulfoxide (DMSO). In some embodiments, the oxygen-containing reactant comprises tetramethylene sulfoxide (TMSO). In some embodiments, the oxygen-containing reactant comprises trimethylamine N-oxide (TMANO). In some embodiments, the oxygen-containing reactant comprises 4-methylmorpholine N-oxide (NMMNO). In some embodiments, the oxygen-containing reactant comprises triethylphosphine oxide (TEPO). The oxygen-containing reactant may be flowed at any suitable flow rate and the flow rate may be adjusted based on the particular application.

The initiator compound of one or more embodiments includes a peroxide and/or an azo compound. As used herein, the “peroxide” includes any compound which has two oxygen atoms that are linked together by a single covalent bond. In one or more embodiments, the peroxide is di-tert-butyl peroxide (DTBP). As used herein, the “azo compound” includes any compound having at least one double-bonded nitrogen group. In one or more embodiments, the azo compound is azobisisobutyronitrile (AIBN). In one or more embodiments, the azo compound is 1,1′-Azobis(cyclohexanecarbonitrile) (ABCN). In some embodiments, the initiator compound (e.g., the peroxide and/or the azo compound) advantageously enables vapor delivery of the initiator compound with no heating required. For example, di-tert-butyl peroxide (DTBP) has a boiling point of 111° C., a vapor pressure of 1 bar at 110° C., and a storage temperature in a range of from 15° C. to 25° C. The initiator compound may be flowed at any suitable flow rate and the flow rate may be adjusted based on the particular application.

It has been advantageously found, in some embodiments, that the initiator compound promotes oxidation of the silicon-containing precursor. It has also been advantageously found that, in the presence of the initiator compound, oxidizing potential increases, which increases the growth rate of the silicon oxide layer deposition compared to silicon oxide deposition without an initiator compound. In some embodiments, the initiator compound reacts with one or more of the silicon-containing precursor or the oxygen-containing reactant to form an activated silicon-containing precursor and/or an activated oxygen-containing reactant. In some embodiments, the initiator compound reacts with the silicon-containing precursor to form an activated silicon-containing precursor. In some embodiments, the initiator compound reacts with the oxygen-containing reactant to form an activated oxygen-containing reactant.

Advantageously, in specific embodiments, the initiator compound reacts with the oxygen-containing reactant and enhances the reactivity of the oxygen-containing reactant. As used herein, the “activated oxygen-containing reactant” refers to the oxygen-containing reactant that has enhanced reactivity based upon the reaction with the initiator compound.

In specific embodiments, the initiator compound comprises di-tert-butyl peroxide (DTBP). Di-tert-butyl peroxide (DTBP) is thermally stable at temperatures of less than or equal to 80° C. Stated differently, di-tert-butyl peroxide (DTBP) thermally decomposes at temperatures greater than 80° C. Thermal decomposition of di-tert-butyl produces radicals to react with one or more of the silicon-containing precursor or the oxygen-containing reactant to form the activated silicon-containing precursor and/or the activated oxygen-containing reactant In specific embodiments where the initiator compound comprises di-tert-butyl peroxide (DTBP), it has been found that thermal decomposition of DTBP produces radicals to react with the oxygen-containing reactant to form the activated oxygen-containing reactant and one or more by-products.

In some embodiments, the thermal decomposition of DTBP produces methyl radical H₃C. It has advantageously found that the one or more by-products of DTBP are volatile, and the one or more by-products do not contaminate the silicon oxide layer 175 deposited in accordance with operation 12.

In one or more embodiments, exposing the semiconductor substrate 102 to the silicon-containing precursor, the oxygen-containing reactant, and the initiator compound (operation 12 of method 10) may be performed for any suitable time period.

The initiator compound advantageously enhances the deposition of the silicon oxide layer 175 in a thermal ALD process. In one or more embodiments where operation 12 of method 10 is a thermal ALD process, operation 12 includes purging the semiconductor substrate 102 with a purge gas selected from argon (Ar), helium (He), and nitrogen (N₂), exposing the semiconductor substrate 102 to the silicon-containing precursor, purging the semiconductor substrate 102 with the purge gas, exposing the semiconductor substrate 102 to the oxygen-containing reactant and the initiator compound, and soaking the semiconductor substrate 102. As used herein, the term “soaking” refers to the static confinement of the reactants (e.g., the oxygen-containing reactant and the initiator compound) in the deposition chamber after they are pulsed/introduced into the deposition chamber. Without intending to be bound by theory, in standard ALD process steps, the precursor(s)/reactant(s) and purge gas are pulsed or introduced into the deposition chamber under active vacuum conditions.

In specific embodiments of the thermal ALD process, the semiconductor substrate 102 is exposed to the silicon-containing precursor for 0.3 seconds delivered at room temperature and a pressure of 200 mTorr, purge gas selected from argon (Ar), helium (He), and nitrogen (N₂), the oxygen-containing reactant for 3 seconds delivered at a temperature in a range of from 70° C. to 85° C. and a pressure in a range of from 20 mTorr to 80 mTorr with the initiator compound for 1.5 seconds delivered at room temperature and a pressure of 80 mTorr to form the activated oxygen-containing reactant, soak for 60 seconds, and purge gas. In one or more embodiments, the thermal ALD process is performed at a temperature less than or equal to 400° C., such as in a range of from room temperature to less than or equal to 400° C.

In specific embodiments, the thermal ALD process of bis(diethylamino)silane (BDEAS) and tetramethylene sulfoxide (TMSO) with di-tert-butyl peroxide (DTBP) deposits a silicon oxide layer at low growth rates. For bis(diethylamino) silane (BDEAS) and trimethylamine N-oxide (TMANO) without an initiator compound, for example, very slow deposition of silicon oxide occurs, which can be significantly increased with di-tert-butyl peroxide (DTBP).

The initiator compound advantageously enhances the deposition of the silicon oxide layer 175 in a thermal CVD process. In one or more embodiments where operation 12 of method 10 is a thermal CVD process, operation 12 includes purging the semiconductor substrate 102 with a purge gas selected from argon (Ar), helium (He), and nitrogen (N₂), exposing the semiconductor substrate 102 to the silicon-containing precursor, the oxygen-containing reactant, and the initiator compound, and purging the semiconductor substrate 102 with the purge gas.

In specific embodiments of the thermal CVD process, the semiconductor substrate 102 is exposed to the silicon-containing precursor for 0.3 seconds delivered at room temperature and a pressure of 200 mTorr, the oxygen-containing reactant for 3 seconds delivered at a temperature in a range of from 70° C. to 85° C. and a pressure in a range of from 20 mTorr to 80 mTorr with the initiator compound for 1.5 seconds delivered at room temperature and a pressure of 80 mTorr to form the activated oxygen-containing reactant. In one or more embodiments, the thermal CVD process is performed at a temperature less than or equal to 400° C., such as in a range of from room temperature to less than or equal to 400° C.

In specific embodiments of the thermal CVD process, the silicon-containing precursor and the oxygen-containing reactant have the same pulse/introduction duration. In specific embodiments of the thermal CVD process, the initiator compound pulse/introduction time can be treated as a regular pulsing interval. The thermal CVD process may be performed for any suitable time period. In some embodiments, for example, the thermal CVD process includes one or more 10-minute cycles, and each 10-minute cycle includes 10 minutes of flowing the silicon-containing precursor and the oxygen-containing reactant, where the initiator compound is pulsed in for a range of 15 seconds to 30 seconds of each minute of the 10-minute cycle. The 10-minute cycle may be repeated any suitable number of times.

In specific embodiments, bis(diethylamino)silane (BDEAS) with tetramethylene sulfoxide (TMSO) and no initiator compound in a thermal CVD process did not deposit a silicon oxide layer. In the presence of di-tert-butyl peroxide (DTBP), a thin silicon oxide layer was deposited by thermal CVD. For trimethylamine N-oxide (TMANO), a silicon oxide layer film was deposited by thermal CVD with di-tert-butyl peroxide (DTBP) increasing the deposition rate.

The silicon oxide layer 175 may have any suitable thickness. The skilled artisan will recognize that the particular thickness of the silicon oxide layer 175 may depend on the particular application. The exposures of operation 12 to deposit the silicon oxide layer 175 may include any suitable time period to deposit the silicon oxide layer 175 to a predetermined thickness.

FIG. 1B illustrates the silicon oxide layer 175 deposited on the top surface 103 of the semiconductor substrate 102. In some embodiments, the silicon oxide layer 175 is deposited directly on the top surface 103 of the semiconductor substrate 102.

FIG. 1C illustrates a semiconductor substrate 102 having at least one feature 150 formed therein. In some embodiments, the at least one feature 150 defines a trench having a top surface 103, two sidewalls 120, and a bottom 130 extending into the semiconductor substrate 102. In some embodiments, the two sidewalls 120 and the bottom 130 are comprised of different materials. In some embodiments, the two sidewalls 120 are comprised of any suitable metallic material and the bottom 130 is comprised of any suitable dielectric material.

FIG. 1D illustrates the silicon oxide layer 175 deposited in the at least one feature 150. In one or more embodiments, the silicon oxide layer 175 is conformal. As used herein, the term “conformal” means that the layer adapts to the contours of a feature, e.g., the at least one feature 150, or a layer. Conformality of a layer is typically quantified by a ratio of the average thickness of a layer deposited on the sidewalls 120 of the at least one feature 150 to the average thickness of the same deposited layer on the field, or top surface 103, of the semiconductor substrate 102. As used herein, a layer that is “conformally deposited” refers to a layer where the thickness is about the same throughout. A layer which is conformal varies in thickness by less than or equal to about 5%, 2%, 1% or 0.5%. In some embodiments, the silicon oxide layer 175 is conformally deposited.

In one or more embodiments, the semiconductor device 100 is a logic device or a memory device. In some embodiments, the semiconductor device 100 is a logic device. In some embodiments, the semiconductor device 100 is a memory device. As will be appreciated by the skilled artisan, the semiconductor device 100 (e.g., the logic device or the memory device) will include the silicon oxide layer 175 along with any additional features or components to form the respective logic device or memory device. The skilled artisan will be able to implement appropriate functionality to a logic device or a memory device based on the above description without undue experimentation.

FIG. 2A illustrates a process flow diagram of a method 20 of manufacturing a semiconductor device 200 according to one or more embodiments of the present disclosure. FIGS. 2B-2D illustrate embodiments of the semiconductor device 200 manufactured in accordance with the method 20.

The method 20 comprises pre-cleaning a semiconductor substrate 202 in a semiconductor processing chamber to remove native oxides (operation 21); exposing the semiconductor substrate 202 to a silicon-containing precursor, a nitrogen-containing reactant, and an initiator compound to deposit a silicon nitride layer 275 directly on a top surface 203 of the semiconductor substrate 202 (operation 22); and optionally, repeating one or more operations of the method 20 (operation 23).

In some embodiments, the method 20 comprises operation 21, operation 22, and operation 23. In some embodiments, the method 20 comprises operation 21 and operation 22. In some embodiments, the method 20 comprises operation 22. In some embodiments, the method 20 consists essentially of operation 21, operation 22, and operation 23. In some embodiments, the method 20 consists essentially of operation 21 and operation 22. In some embodiments, the method 20 consists essentially of operation 22. In some embodiments, the method 20 consists of operation 21, operation 22, and operation 23. In some embodiments, the method 20 consists of operation 21 and operation 22. In some embodiments, the method 20 consists of operation 22.

The semiconductor substrate 202 of FIGS. 2B-2D may be the same as the semiconductor substrate 102 of FIGS. 1B-1D described herein. The pre-cleaning operation 21 of method 20 may be the same as pre-cleaning operation 11 of method 10 as described herein.

In some embodiments, at operation 22, the method 20 includes exposing the semiconductor substrate 202 to a silicon-containing precursor, a nitrogen-containing reactant, and an initiator compound to deposit a silicon nitride layer 275 directly on a top surface 203 of the semiconductor substrate 202. Each of the silicon-containing precursor, the nitrogen-containing reactant, and the initiator compound may be suitable for vapor delivery. In some embodiments, operation 22 includes a thermal chemical vapor deposition (CVD) process or a thermal atomic layer deposition (ALD) process.

The silicon-containing precursor, the nitrogen-containing reactant, and the initiator compound can be flowed in any suitable order to deposit the silicon nitride layer 275. In some embodiments, the silicon-containing precursor, the nitrogen-containing reactant, and the initiator compound are flowed individually in a sequential order. In some embodiments, one or more of the silicon-containing precursor, the nitrogen-containing reactant, and the initiator compound are flowed simultaneously together (e.g., co-flowed).

In some embodiments, the silicon-containing precursor, the nitrogen-containing reactant, and the initiator compound are flowed sequentially in the order of the silicon-containing precursor, then the nitrogen-containing reactant, then the initiator compound. In some embodiments, the silicon-containing precursor, the nitrogen-containing reactant, and the initiator compound are flowed sequentially in the order of the nitrogen-containing reactant, then the silicon-containing precursor, then the initiator compound. In some embodiments, the silicon-containing precursor, nitrogen-containing reactant, and the initiator compound are flowed sequentially in the order of the initiator compound, then the silicon-containing precursor, then the nitrogen-containing reactant.

In one or more embodiments, the silicon-containing precursor, the nitrogen-containing reactant, and the initiator compound are flowed simultaneously together (e.g., co-flowed).

In some embodiments, the silicon-containing precursor is flowed, followed by co-flowing the nitrogen-containing reactant and the initiator compound. The nitrogen-containing reactant and the initiator compound can be flowed for the same duration of time or different durations of time.

In some embodiments, the silicon-containing precursor is flowed, followed by co-flowing the nitrogen-containing reactant and the initiator compound. The nitrogen-containing reactant and the initiator compound can be flowed for the same duration of time or different durations of time.

In one or more embodiments, the silicon-containing precursor and the initiator compound are co-flowed, followed by flowing the nitrogen-containing reactant. The silicon-containing precursor and the initiator compound can be flowed for the same duration of time or different durations of time.

In specific embodiments, operation 22 of method 20 is a pulsed CVD (pCVD) method where one or more of the silicon-containing precursor, the nitrogen-containing reactant, and the initiator compound are flowed constantly, and at least one of the other of the silicon-containing precursor, the nitrogen-containing reactant, and the initiator compound is pulsed at a regular interval (e.g., pulsed intermittently) into the semiconductor processing chamber. In specific embodiments where operation 22 of method 20 is a pulsed CVD (pCVD) method, the silicon-containing precursor and the nitrogen-containing reactant are flowed constantly and the initiator compound is pulsed intermittently.

The nitrogen-containing reactant may be any suitable reactant. In some embodiments, the nitrogen-containing reactant comprises a substituted or unsubstituted amine group. In one or more embodiments, the nitrogen-containing reactant is ammonia (NH₃). In one or more embodiments, the nitrogen-containing reactant has a formula of R₂N—NR₂, where each R is independently hydrogen, an alkyl group, an aryl group, a sulfonyl group, or an acyl group. In one or more embodiments, the nitrogen-containing reactant has a formula of

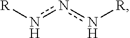

where each R is independently hydrogen, an alkyl group, an aryl group, a sulfonyl group, or an acyl group. The nitrogen-containing reactant may be flowed at any suitable flow rate and the flow rate may be adjusted based on the particular application.

It has been advantageously found that, in the presence of the initiator compound, deposition temperature of the silicon nitride layer 275 is reduced compared to processes where an initiator compound is not used.

Embodiments of the disclosure advantageously provide methods where the silicon nitride layer has a reduced hydrogen content compared to a process where an initiator compound is not used. Stated differently, the initiator compound described herein advantageously provides silicon nitride layers, e.g., silicon nitride layer 275 having a reduced hydrogen content relative to a silicon nitride deposition process that does not employ an initiator compound.

It has been found that the methyl radical H₃C. produced by the thermal decomposition of DTBP removes hydrogen (H) atoms from the deposited silicon nitride layer, e.g., silicon nitride layer 275, thereby reducing the hydrogen content of the silicon nitride layer. Without intending to be bound by theory, it is also thought that the hydrogen content of the silicon nitride layer 275 can be reduced at elevated process temperatures, such as, for example, greater than 400° C.

The hydrogen content of the silicon nitride layer 275 can be determined by any suitable method known to the skilled artisan. For example, hydrogen content can be evaluated by refractive index of the silicon nitride layer, e.g., silicon nitride layer 275. For example, current silicon nitride layers formed from SiCl₄ and NH₃ has a refractive index of about 1.73. As used herein, a “high” hydrogen content corresponds to a refractive index of less than or equal to 1.9. As used herein, a “low” hydrogen content corresponds to a refractive index in a range of from 1.9 to 2.1. In one or more embodiments, the silicon nitride layer 275 has a low hydrogen content, which corresponds to a refractive index in a range of from 1.9 to 2.1.

In some embodiments, the initiator compound reacts with one or more of the silicon-containing precursor or the nitrogen-containing reactant to form an activated silicon-containing precursor and/or an activated nitrogen-containing reactant. In some embodiments, the initiator compound reacts with the silicon-containing precursor to form an activated silicon-containing precursor. In some embodiments, the initiator compound reacts with the nitrogen-containing reactant to form an activated nitrogen-containing reactant.

Advantageously, in specific embodiments, the initiator compound reacts with the nitrogen-containing reactant and enhances the reactivity of the nitrogen-containing reactant. As used herein, the “activated nitrogen-containing reactant” refers to the nitrogen-containing reactant that has enhanced reactivity based upon the reaction with the initiator compound.

In one or more embodiments where operation 22 of method 20 is a thermal ALD process, operation 22 includes purging the semiconductor substrate 202 with a purge gas selected from argon (Ar), helium (He), and nitrogen (N₂), exposing the semiconductor substrate 202 to the silicon-containing precursor, purging the semiconductor substrate 202 with a purge gas selected from argon (Ar), helium (He), and nitrogen (N₂), exposing the semiconductor substrate 202 to the nitrogen-containing reactant and the initiator compound, and soaking the semiconductor substrate 202.

In specific embodiments of the thermal ALD process, the semiconductor substrate 202 is exposed to the silicon-containing precursor for 5 seconds delivered at room temperature and a pressure of 5 Torr, purge gas selected from argon (Ar), helium (He), and nitrogen (N₂), the nitrogen-containing reactant for 5 seconds delivered at a temperature in a range of from room temperature to 40° C. and a pressure of 30 Torr, with the initiator compound for 2.5 seconds delivered at room temperature and a pressure of 80 mTorr to form the activated nitrogen-containing reactant, soak for 60 seconds, and purge gas. In one or more embodiments, the thermal ALD process is performed at a temperature less than or equal to 400° C., such as in a range of from room temperature to less than or equal to 400° C.

In one or more embodiments where operation 22 of method 20 is a thermal CVD process, operation 22 includes purging the semiconductor substrate 202 with a purge gas selected from argon (Ar), helium (He), and nitrogen (N₂), exposing the semiconductor substrate 202 to the silicon-containing precursor, the nitrogen-containing reactant, and the initiator compound, and purging the semiconductor substrate 202 with the purge gas.

In specific embodiments of the thermal CVD process, the semiconductor substrate 202 is exposed to the silicon-containing precursor for 5 seconds delivered at room temperature and a pressure of 5 Torr, the nitrogen-containing reactant for 5 seconds delivered at a temperature in a range of from room temperature to 40° C. and a pressure of 30 Torr, with the initiator compound for 2.5 seconds delivered at room temperature and a pressure of 80 mTorr to form the activated nitrogen-containing reactant. In one or more embodiments, the thermal CVD process is performed at a temperature less than or equal to 400° C., such as in a range of from room temperature to less than or equal to 400° C.

The silicon nitride layer 275 may have any suitable thickness. The skilled artisan will recognize that the particular thickness of the silicon nitride layer 275 may depend on the particular application. The exposures of operation 22 to deposit the silicon nitride layer 275 may include any suitable time period to deposit the silicon nitride layer 275 to a predetermined thickness.

FIG. 2B illustrates the silicon nitride layer 275 deposited on the top surface 203 of the semiconductor substrate 202. In some embodiments, the silicon nitride layer 275 is deposited directly on the top surface 203 of the semiconductor substrate 202. FIG. 2C illustrates a semiconductor substrate 202 having at least one feature 250 formed therein. In some embodiments, the at least one feature 250 defines a trench having a top surface 203, two sidewalls 220, and a bottom 230 extending into the semiconductor substrate 202. In some embodiments, the two sidewalls 220 and the bottom 230 are comprised of different materials. In some embodiments, the two sidewalls 220 are comprised of any suitable metallic material and the bottom 230 is comprised of any suitable dielectric material.

FIG. 2D illustrates the silicon nitride layer 275 deposited in the at least one feature 250. In one or more embodiments, the silicon nitride layer 275 is conformal. In some embodiments, the silicon nitride layer 275 is conformally deposited in the at least one feature 250.

In one or more embodiments, the semiconductor device 200 is a logic device or a memory device. In some embodiments, the semiconductor device 200 is a logic device. In some embodiments, the semiconductor device 200 is a memory device. As will be appreciated by the skilled artisan, the semiconductor device 200 (e.g., the logic device or the memory device) will include the silicon nitride layer 275 along with any additional features or components to form the respective logic device or memory device. The skilled artisan will be able to implement appropriate functionality to a logic device or a memory device based on the above description without undue experimentation.

FIG. 3A illustrates a process flow diagram of a method 30 of manufacturing a semiconductor device 300 according to one or more embodiments of the present disclosure. FIGS. 3B-3D illustrate embodiments of the semiconductor device 300 manufactured in accordance with the method 30.

The method 30 comprises pre-cleaning a semiconductor substrate 302 in a semiconductor processing chamber to remove native oxides (operation 31); exposing the semiconductor substrate 302 to a silicon-containing precursor, an oxygen-containing reactant, a nitrogen-containing reactant, and an initiator compound to deposit a silicon oxynitride layer 375 directly on a top surface 303 of the semiconductor substrate 302 (operation 32); and optionally, repeating one or more operations of the method 30 (operation 33).

In some embodiments, the method 30 comprises operation 31, operation 32, and operation 33. In some embodiments, the method 30 comprises operation 31 and operation 32. In some embodiments, the method 30 comprises operation 32. In some embodiments, the method 30 consists essentially of operation 31, operation 32, and operation 33. In some embodiments, the method 30 consists essentially of operation 31 and operation 32. In some embodiments, the method 30 consists essentially of operation 32. In some embodiments, the method 30 consists of operation 31, operation 32, and operation 33. In some embodiments, the method 30 consists of operation 31 and operation 32. In some embodiments, the method 30 consists of operation 32.

The semiconductor substrate 302 of FIGS. 3B-3D may be the same as the semiconductor substrate 102 of FIGS. 1B-1D and/or the semiconductor substrate 202 of FIGS. 2B-2D described herein. The pre-cleaning operation 31 of method 30 may be the same as pre-cleaning operation 11 of method 10 and/or pre-cleaning operation 21 of method 20 as described herein.

In some embodiments, at operation 32, the method 30 includes exposing the semiconductor substrate 302 to a silicon-containing precursor, an oxygen-containing reactant, a nitrogen-containing reactant, and an initiator compound to deposit a silicon oxynitride layer 375 directly on a top surface 303 of the semiconductor substrate 302. Each of the silicon-containing precursor, the oxygen-containing reactant, the nitrogen-containing reactant, and the initiator compound may be suitable for vapor delivery. In some embodiments, operation 32 includes a thermal chemical vapor deposition (CVD) process or a thermal atomic layer deposition (ALD) process.

The silicon-containing precursor, the oxygen-containing reactant, the nitrogen-containing reactant, and the initiator compound can be flowed in any suitable order to deposit the silicon oxynitride layer 375. In some embodiments, the silicon-containing precursor, the oxygen-containing reactant, the nitrogen-containing reactant, and the initiator compound are flowed individually in a sequential order. In some embodiments, one or more of the silicon-containing precursor, the oxygen-containing reactant, the nitrogen-containing reactant, and the initiator compound are flowed simultaneously together (e.g., co-flowed).

In one or more embodiments, the silicon-containing precursor, the oxygen-containing reactant, the nitrogen-containing reactant, and the initiator compound are flowed sequentially in the order of the silicon-containing precursor, then the oxygen-containing reactant, then the nitrogen-containing reactant, then the initiator compound. In one or more embodiments, the silicon-containing precursor, the oxygen-containing reactant, the nitrogen-containing reactant, and the initiator compound are flowed sequentially in the order of the initiator compound, then the silicon-containing precursor, then the oxygen-containing reactant, then the nitrogen-containing reactant. In one or more embodiments, the silicon-containing precursor, the oxygen-containing reactant, the nitrogen-containing reactant, and the initiator compound are flowed sequentially in the order of the initiator compound, then the silicon-containing precursor, then the nitrogen-containing reactant, then the oxygen-containing reactant.

In one or more embodiments, the silicon-containing precursor, the oxygen-containing reactant, the nitrogen-containing reactant, and the initiator compound are flowed simultaneously together (e.g., co-flowed).

In one or more embodiments, the silicon-containing precursor is flowed, followed by co-flowing the oxygen-containing reactant, the nitrogen-containing reactant, and the initiator compound. The oxygen-containing reactant, the nitrogen-containing reactant and the initiator compound can be flowed for the same duration of time or different durations of time.

In one or more embodiments, the silicon-containing precursor and the initiator compound are co-flowed, followed by flowing the nitrogen-containing reactant and the oxygen-containing reactant in any suitable order. The silicon-containing precursor and the initiator compound can be flowed for the same duration of time or different durations of time.

In specific embodiments, operation 32 of method 30 is a pulsed CVD (pCVD) method where one or more of the silicon-containing precursor, the oxygen-containing reactant, the nitrogen-containing reactant, and the initiator compound are flowed constantly, and at least one of the other of the silicon-containing precursor, the oxygen-containing reactant, the nitrogen-containing reactant, and the initiator compound is pulsed at a regular interval (e.g., pulsed intermittently) into the semiconductor processing chamber. In specific embodiments where operation 32 of method 30 is a pulsed CVD (pCVD) method, the silicon-containing precursor, the oxygen-containing reactant, and the nitrogen-containing reactant are flowed constantly, and the initiator compound is pulsed intermittently.

FIG. 3B illustrates the silicon oxynitride layer 375 deposited on the top surface 303 of the semiconductor substrate 302. In some embodiments, the silicon oxynitride layer 375 is deposited directly on the top surface 303 of the semiconductor substrate 302.

FIG. 3C illustrates a semiconductor substrate 302 having at least one feature 350 formed therein. In some embodiments, the at least one feature 350 defines a trench having a top surface 303, two sidewalls 320, and a bottom 330 extending into the semiconductor substrate 302. In some embodiments, the two sidewalls 320 and the bottom 330 are comprised of different materials. In some embodiments, the two sidewalls 320 are comprised of any suitable metallic material and the bottom 330 is comprised of any suitable dielectric material.

FIG. 3D illustrates the silicon oxynitride layer 375 deposited in the at least one feature 350. In one or more embodiments, the silicon oxynitride layer 375 is conformal. In some embodiments, the silicon oxynitride layer 375 is conformally deposited in the at least one feature 350.

In one or more embodiments, the semiconductor device 300 is a logic device or a memory device. In some embodiments, the semiconductor device 300 is a logic device. In some embodiments, the semiconductor device 300 is a memory device. As will be appreciated by the skilled artisan, the semiconductor device 300 (e.g., the logic device or the memory device) will include the silicon oxynitride layer 375 along with any additional features or components to form the respective logic device or memory device. The skilled artisan will be able to implement appropriate functionality to a logic device or a memory device based on the above description without undue experimentation.

According to one or more embodiments, the semiconductor processing chamber in which the methods, e.g., method 10, method 20, and/or method 30 are performed can be maintained at processing conditions, and the processing conditions may be modified based on the particular application. In specific embodiments, as will be appreciated by the skilled artisan, the processing conditions may be modified based upon the type of semiconductor device being manufactured, e.g., a logic device or a memory device.

The semiconductor processing chamber in which the methods, e.g., method 10, method 20, and/or method 30 are performed can be maintained at any suitable temperature. In some embodiments, the semiconductor processing chamber is maintained at a temperature in a range of from 0° C. to 400° C. In some embodiments, the semiconductor processing chamber is maintained at a temperature in a range of from 10° C. to 400° C., in a range of from 20° C. to 400° C., in a range of from 25° C. to 400° C. in a range of from 30° C. to 400° C., in a range of from 50° C. to 400° C., in a range of from 100° C. to 400° C., in a range of from 110° C. to 400° C., in a range of from 130° C. to 400° C., or in a range of from 200° C. to 400° C.

Additional embodiments of the disclosure are directed to processing tools (i.e., a cluster tool) 900 for the formation of the semiconductor devices and methods described herein, as shown in FIG. 4. The cluster tool 900 includes at least one central transfer station 921, 931 with a plurality of sides. A robot 925, 935 is positioned within the central transfer station 921, 931 and is configured to move a robot blade and a wafer to each of the plurality of sides.

The cluster tool 900 comprises a plurality of processing chambers 902, 904, 906, 908, 910, 912, 914, 916, and 918, also referred to as process stations, connected to the central transfer station 921, 931. The various processing chambers provide separate processing regions isolated from adjacent process stations. The processing chamber can be any suitable chamber including, but not limited to, a pre-cleaning chamber, a buffer chamber, transfer space(s), a wafer orienter/degas chamber, a cryo cooling chamber, a deposition chamber, annealing chamber, etching chamber, a thermal processing (RTP) chamber, a plasma oxidation chamber, a plasma nitridation chamber, an atomic layer deposition (ALD) chamber, including a thermal ALD chamber, and a chemical vapor deposition (CVD) chamber, including a thermal CVD chamber.

In one or more embodiments, the cluster tool 900 is an integrated system such that the operations of method 10, method 20, and/or method 30 are performed in situ. In some embodiments, one or more of the operations of method 10, method 20, and/or method 30 are performed ex situ in the cluster tool 900.

In one or more embodiments, the cluster tool 900 includes a pre-cleaning chamber connected to the central transfer station. In one or more embodiments, the cluster tool 900 includes a pre-cleaning chamber and an atomic layer deposition (ALD) chamber, including a thermal ALD chamber, or a pre-cleaning chamber and a chemical vapor deposition (CVD) chamber, including a thermal CVD chamber connected to the central transfer station, such that there is no vacuum break in between the operations of method 10, method 20, and/or method 30.

The particular arrangement of processing chambers and components can be varied depending on the cluster tool and should not be taken as limiting the scope of the disclosure.

In the embodiment shown in FIG. 4, a factory interface 950 is connected to a front of the cluster tool 900. The factory interface 950 includes a loading chamber 954 and an unloading chamber 956 on a front 951 of the factory interface 950. While the loading chamber 954 is shown on the left and the unloading chamber 956 is shown on the right, those skilled in the art will understand that this is merely representative of one possible configuration.

The size and shape of the loading chamber 954 and unloading chamber 956 can vary depending on, for example, the substrates being processed in the cluster tool 900. In the embodiment shown, the loading chamber 954 and unloading chamber 956 are sized to hold a wafer cassette with a plurality of wafers positioned within the cassette.

A robot 952 is within the factory interface 950 and can move between the loading chamber 954 and the unloading chamber 956. The robot 952 is capable of transferring a wafer from a cassette in the loading chamber 954 through the factory interface 950 to load lock chamber 960. The robot 952 is also capable of transferring a wafer from the load lock chamber 962 through the factory interface 950 to a cassette in the unloading chamber 956. As will be understood by those skilled in the art, the factory interface 950 can have more than one robot 952. For example, the factory interface 950 may have a first robot that transfers wafers between the loading chamber 954 and load lock chamber 960, and a second robot that transfers wafers between the load lock chamber 962 and the unloading chamber 956.

The cluster tool 900 shown in FIG. 4 has a first section 920 and a second section 930. The first section 920 is connected to the factory interface 950 through load lock chambers 960, 962. The first section 920 includes a first transfer chamber 921 with at least one robot 925 positioned therein. The robot 925 is also referred to as a robotic wafer transport mechanism. The first transfer chamber 921 is centrally located with respect to the load lock chambers 960, 962, processing chambers 902, 904, 916, 918, and pass-through chambers 922, 924. The robot 925 of some embodiments is a multi-arm robot capable of independently moving more than one wafer at a time. In one or more embodiments, the first transfer chamber 921 comprises more than one robotic wafer transfer mechanism. The robot 925 in first transfer chamber 921 is configured to move wafers between the chambers around the first transfer chamber 921. Individual wafers are carried upon a wafer transport blade that is located at a distal end of the first robotic mechanism.

After processing a wafer in the first section 920, the wafer can be passed to the second section 930 through a pass-through chamber. For example, pass-through chambers 922, 924 can be uni-directional or bi-directional pass-through chambers. The pass-through chambers 922, 924 can be used, for example, to cryo cool the wafer before processing in the second section 930 or to allow wafer cooling or post-processing before moving back to the first section 920.

A system controller 990 is in communication with the first robot 925, second robot 935, first plurality of processing chambers 902, 904, 916, 918 and second plurality of processing chambers 906, 908, 910, 912, 914. The system controller 990 can be any suitable component that can control the processing chambers and robots. For example, the system controller 990 can be a computer including a central processing unit, memory, suitable circuits, and storage.

Processes may generally be stored in the memory of the system controller 990 as a software routine that, when executed by the processor, causes the process chamber to perform processes of the present disclosure. The software routine may also be stored and/or executed by a second processor (not shown) that is remotely located from the hardware being controlled by the processor. Some or all of the methods of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor, transforms the general-purpose computer into a specific purpose computer (controller) that controls the chamber operation such that the processes are performed.

Embodiments of the disclosure are directed to a non-transitory computer readable medium. In one or more embodiments, the non-transitory computer readable medium includes instructions that, when executed by a controller of a processing chamber, causes the processing chamber to perform the operations of any of the methods described herein. In one or more embodiments, the controller causes the processing chamber to perform one or more of the operations of method 10, method 20, and/or method 30.

The disclosure is now described with reference to the following Examples. Before describing several exemplary embodiments of the disclosure, it is to be understood that the disclosure is not limited to the details of construction or process steps set forth in the following description. The disclosure is capable of other embodiments and of being practiced or being carried out in various ways.

### EXAMPLES

### Comparative Example 1

A silicon-containing precursor comprising tetrakis(ethylsulfanyl) silane and an oxygen-containing reactant comprising dimethyl sulfoxide (DMSO) were reacted for 14 days at a temperature of 50° C., and about 9% of the respective precursor and reactant were converted (e.g., reacted) in forming a silicon oxide layer. The conversion of about 9% demonstrates poor silicon oxide layer growth.

### Comparative Example 2

A silicon-containing precursor comprising tetrakis(ethylsulfanyl) silane and an oxygen-containing reactant comprising dimethyl sulfoxide (DMSO) were reacted for 19.5 hours at a temperature of 110° C., and about 4% of the respective precursor and reactant were converted (e.g., reacted) in forming a silicon oxide layer. The conversion of about 4% demonstrates poor silicon oxide layer growth.

### Comparative Example 3

A silicon-containing precursor comprising tetrakis(phenylsulfanyl) silane and an oxygen-containing reactant comprising dimethyl sulfoxide (DMSO) were reacted for 3 days at a temperature of 50° C., and about 78% of the respective precursor and reactant were converted (e.g., reacted) in forming a silicon oxide layer. The conversion of about 78% demonstrates improved silicon oxide layer growth relative to Comparative Example 1 and Comparative Example 2.

### Comparative Example 4

A silicon-containing precursor comprising tetrakis(2,2,2-trifluoroethyl) tetrathiosilicate and an oxygen-containing reactant comprising dimethyl sulfoxide (DMSO) were reacted for 6 days at room temperature, and about 100% of the respective precursor and reactant were converted (e.g., reacted) in forming a silicon oxide layer. The conversion of about 100% demonstrates improved silicon oxide layer growth relative to Comparative Examples 1-3.

### Comparative Example 5

A silicon-containing precursor comprising tetrakis(2,2,2-trifluoroethyl) tetrathiosilicate and an oxygen-containing reactant comprising tetramethylene sulfoxide (TMSO) were reacted for 1 day at room temperature, and about 100% of the respective precursor and reactant were converted (e.g., reacted) in forming a silicon oxide layer. The conversion of about 100% demonstrates improved silicon oxide layer growth relative to Comparative Examples 1-3. Advantageously, it has been found that reacting tetrakis(2,2,2-trifluoroethyl) tetrathiosilicate and tetramethylene sulfoxide (TMSO) resulted in a conversion of about 100% in ⅙ the amount of time of the reaction in Comparative Example 4 where dimethyl sulfoxide (DMSO) was used.

### Comparative Example 6

In a first experiment, a silicon-containing precursor comprising tetrakis(2,2,2-trifluoroethyl) tetrathiosilicate and an oxygen-containing reactant comprising dimethyl sulfoxide (DMSO) were reacted for 6 days at room temperature, and about 100% of the respective precursor and reactant were converted (e.g., reacted) in forming a silicon oxide layer.

In a second experiment, a silicon-containing precursor comprising tetrakis(2,2,2-trifluoroethyl) tetrathiosilicate, an oxygen-containing reactant comprising dimethyl sulfoxide (DMSO), and a co-reagent comprising cylochexa-1,3-diene were reacted for 9 days at room temperature, and about 54% of the respective precursor and reactant were converted (e.g., reacted) in forming a silicon oxide layer.

The second experiment demonstrates that the co-reagent comprising cylochexa-1,3-diene inhibits the reaction of tetrakis(2,2,2-trifluoroethyl) tetrathiosilicate and dimethyl sulfoxide (DMSO).

### Inventive Example 1

A series of experiments were performed using no initiator compound, an initiator compound comprising 1,1′-Azobis(cyclohexanecarbonitrile) (ABCN), and an initiator compound comprising di-tert-butyl peroxide (DTBP) to determine whether a reaction occurred with tetrakis(ethylsulfanyl) silane and dimethyl sulfoxide (DMSO) to form a silicon oxide layer. Each of the experiments were performed for 19.5 hours at a temperature of 110° C.

In the first experiment where tetrakis(ethylsulfanyl) silane and dimethyl sulfoxide (DMSO) were reacted with no initiator compound, a conversion of about 4% was observed. In the second experiment where tetrakis(ethylsulfanyl) silane and dimethyl sulfoxide (DMSO) were reacted with the initiator compound comprising 1,1′-Azobis(cyclohexanecarbonitrile) (ABCN), a conversion of about 5% was observed. In the third experiment where tetrakis(ethylsulfanyl) silane and dimethyl sulfoxide (DMSO) were reacted with the initiator compound comprising di-tert-butyl peroxide (DTBP), a conversion of about 26% was observed. Advantageously, the third experiment exhibited a conversion about 6 times greater than the conversion of each of the first experiment and the second experiment, demonstrating that the initiator compound comprising di-tert-butyl peroxide (DTBP) enhanced silicon oxide deposition.

### Inventive Example 2

A series of experiments were performed using an initiator compound comprising di-tert-butyl peroxide (DTBP) with differing silicon-containing precursors and oxygen-containing reactants to determine whether a reaction occurred. Each of the experiments were performed for 6.5 hours at a temperature of 130° C.

In a first experiment, a silicon-containing precursor comprising bis(diethylamino) silane (BDEAS), an oxygen-containing reactant comprising tetramethylene sulfoxide (TMSO), and the initiator compound di-tert-butyl peroxide (DTBP) were reacted. The first experiment resulted in a reaction between the silicon-containing precursor, the oxygen-containing reactant, and the initiator compound, and the formation of a silicon oxide layer.

In a second experiment, a silicon-containing precursor comprising bis(diethylamino) silane (BDEAS) and an oxygen-containing reactant comprising tetramethylene sulfoxide (TMSO) were reacted with no initiator compound. The second experiment did not result in a reaction between the silicon-containing precursor and the oxygen-containing reactant, or formation of a silicon oxide layer.

In a third experiment, a silicon-containing precursor comprising bis(diethylamino) silane (BDEAS), an oxygen-containing reactant comprising dimethyl sulfoxide (DMSO), and the initiator compound di-tert-butyl peroxide (DTBP) were reacted. The third experiment resulted in a reaction between the silicon-containing precursor, the silicon-containing reactant, and the initiator compound, and the formation of a silicon oxide layer.

In a fourth experiment, a silicon-containing precursor comprising bis(diethylamino) silane (BDEAS) and an oxygen-containing reactant comprising dimethyl sulfoxide (DMSO) were reacted with no initiator compound. The fourth experiment did not result in a reaction between the precursor and the reactant, or formation of a silicon oxide layer.

In a fifth experiment, a silicon-containing precursor comprising tris(dimethylamino) silane (3DMAS), an oxygen-containing reactant comprising dimethyl sulfoxide (DMSO), and the initiator compound di-tert-butyl peroxide (DTBP) were reacted. The fifth experiment resulted in a reaction between the precursor, the reactant, and the initiator compound, and the formation of a silicon oxide layer.

In a sixth experiment, a silicon-containing precursor comprising tris(dimethylamino) silane (3DMAS) and an oxygen-containing reactant comprising dimethyl sulfoxide (DMSO) were reacted with no initiator compound. The sixth experiment unexpectedly resulted in a reaction between the silicon-containing precursor and the oxygen-containing reactant, and the formation of a silicon oxide layer. The silicon oxide layer formed in the sixth experiment formed at a significantly slower rate than the silicon oxide layer formed in the experiments where the initiator compound comprising di-tert-butyl peroxide (DTBP) was used.

In a seventh experiment, a silicon-containing precursor comprising tetrakis(dimethylamino) silane (4DMAS), an oxygen-containing reactant comprising dimethyl sulfoxide (DMSO), and the initiator compound di-tert-butyl peroxide (DTBP) were reacted. The seventh experiment resulted in a reaction between the silicon-containing precursor, the oxygen-containing reactant, and the initiator compound, and the formation of a silicon oxide layer.

In an eighth experiment, a silicon-containing precursor comprising tetrakis(dimethylamino) silane (4DMAS) and an oxygen-containing reactant comprising dimethyl sulfoxide (DMSO) were reacted with no initiator compound. The eighth experiment unexpectedly resulted in a reaction between the silicon-containing precursor and the oxygen-containing reactant, and the formation of a silicon oxide layer. The silicon oxide layer formed in the eighth experiment formed at a significantly slower rate than the silicon oxide layer formed in the experiments where the initiator compound comprising di-tert-butyl peroxide (DTBP) was used.

Advantageously, Inventive Examples 1 and 2 demonstrate that the initiator compound enables silicon oxide deposition otherwise did not occur (based upon the specific silicon-containing precursor and oxygen-containing reactant) and enhances the silicon oxide deposition rate with differing silicon-containing precursors and oxygen-containing reactants.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A method of manufacturing a semiconductor device, the method comprising:
exposing a semiconductor substrate in a semiconductor processing chamber to a silicon-containing precursor, an oxygen-containing reactant, and an initiator compound to deposit a silicon oxide layer, wherein the initiator compound reacts with one or more of the silicon-containing precursor or the oxygen-containing reactant to form an activated silicon-containing precursor and/or an activated oxygen-containing reactant.

2. The method of claim 1, further comprising pre-cleaning the semiconductor substrate to remove native oxides prior to depositing the silicon oxide layer.

3. The method of claim 1, wherein the silicon-containing precursor comprises one or more of an aminosilane, a silylamine, a thiosilane, a halosilane, or an alkoxysilane.

4. The method of claim 1, wherein the initiator compound comprises one or more of di-tert-butyl peroxide (DTBP) or azobisisobutyronitrile (AIBN).

5. The method of claim 1, wherein the oxygen-containing reactant comprises one or more of a sulfoxide, an amine N-oxide, or a phosphine oxide.

6. The method of claim 1, wherein the method is a thermal chemical vapor deposition (CVD) process or a thermal atomic layer deposition (ALD) process.

7. The method of claim 6, wherein the silicon-containing precursor, oxygen-containing reactant, and the initiator compound are co-flowed.

8. The method of claim 6, wherein the method is performed at a temperature less than or equal to 400° C. and the semiconductor substrate is exposed to the silicon-containing precursor for 0.3 seconds delivered at room temperature and a pressure of 200 mTorr, purge gas, the oxygen-containing reactant for 3 seconds delivered at a temperature in a range of from 70° C. to 85° C. and a pressure in a range of from 20 mTorr to 80 mTorr with the initiator compound for 1.5 seconds delivered at room temperature and a pressure of 80 mTorr to form the activated oxygen-containing reactant, soak for 60 seconds, and purge gas.

9. The method of claim 8, wherein the purge gas is selected from argon (Ar), helium (He), and nitrogen (N₂).

10. The method of claim 1, comprising repeating the method at a temperature in a range of from 100° C. to 400° C.

11. A method of manufacturing a semiconductor device, the method comprising:
exposing a semiconductor substrate in a semiconductor processing chamber to a silicon-containing precursor, a nitrogen-containing reactant, and an initiator compound to deposit a silicon nitride layer, wherein the initiator compound reacts with one or more of the silicon-containing precursor or the nitrogen-containing reactant to form an activated silicon-containing precursor and/or an activated nitrogen-containing reactant.

12. The method of claim 11, further comprising pre-cleaning the semiconductor substrate to remove native oxides prior to depositing the silicon nitride layer.

13. The method of claim 11, wherein the silicon-containing precursor comprises one or more of an aminosilane, a silylamine, a thiosilane, a halosilane, or an alkoxysilane.

14. The method of claim 11, wherein the initiator compound comprises one or more of di-tert-butyl peroxide (DTBP) or azobisisobutyronitrile (AIBN).

15. The method of claim 11, wherein the nitrogen-containing reactant comprises a substituted or unsubstituted amine group.

16. The method of claim 11, wherein the method is a thermal chemical vapor deposition (CVD) process or a thermal atomic layer deposition (ALD) process.

17. The method of claim 16, wherein the silicon-containing precursor, nitrogen-containing reactant, and the initiator compound are co-flowed.

18. The method of claim 16, wherein method is performed at a temperature less than or equal to 400° C. and the semiconductor substrate is exposed to the silicon-containing precursor for 5 seconds delivered at room temperature and a pressure of 200 mTorr, purge gas selected from argon (Ar), helium (He), and nitrogen (N₂), the nitrogen-containing reactant for 5 seconds delivered at a temperature in a range of from room temperature to 40° C. and a pressure of 80 mTorr with the initiator compound for 2.5 seconds delivered at room temperature and a pressure of 80 mTorr to form the activated nitrogen-containing reactant, soak for 60 seconds, and purge gas.

19. The method of claim 11, wherein the silicon nitride layer has a reduced hydrogen content compared to a process where an initiator compound is not used.

20. A method of manufacturing a semiconductor device, the method comprising:
exposing a semiconductor substrate in a semiconductor processing chamber to a silicon-containing precursor, an oxygen-containing reactant, a nitrogen-containing reactant, and an initiator compound to deposit a silicon oxynitride layer, wherein the initiator compound reacts with one or more of the silicon-containing precursor, the oxygen-containing reactant, or the nitrogen-containing reactant to form an activated silicon-containing precursor, an activated oxygen-containing reactant, and/or an activated nitrogen-containing reactant.
